(19) United States
(12) Patent Application Publication
(10) Pub. No.: US 2014/0127404 A1
(43) Pub. Date: May 8, 2014

(54) Apparatus For Spatial Atomic Layer Deposition With Recirculation And Methods Of Use

(71) Applicants: Joseph Yudovsky, Campbell, CA (US); Hemant P. Mungekar, Campbell, CA (US); Michael S. Cox, Gilroy, CA (US); Zheng Yuan, Cupertino, CA (US)

(72) Inventors: Joseph Yudovsky, Campbell, CA (US); Hemant P. Mungekar, Campbell, CA (US); Michael S. Cox, Gilroy, CA (US); Zheng Yuan, Cupertino, CA (US)

(21) Appl. No.: 14/073,114

(22) Filed: Nov. 6, 2013

Related U.S. Application Data
(60) Provisional application No. 61/723,063, filed on Nov. 6, 2012.

(51) Int. Cl. C23C 16/455

(52) U.S. Cl. CPC C23C 16/455
USPC 427/248.1; 118/715

(57) ABSTRACT

Provided are atomic layer deposition apparatus and methods including a plurality of elongate gas ports and pump ports in communication with multiple conduits to transport the gases from the processing chamber to be condensed, stored and/or recirculated.

### CROSS-REFERENCE TO RELATED APPLICATIONS

This application claims priority to U.S. Provisional Application No. 61/723,063, filed Nov. 6, 2012.

### BACKGROUND

Embodiments of the invention generally relate to an apparatus and a method for depositing materials. More specifically, embodiments of the invention are directed to atomic layer deposition chambers with multiple gas distribution plates.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are sequentially introduced into a process chamber containing a substrate. Generally, a first reactant is introduced into a process chamber and is adsorbed onto the substrate surface. A second reactant is then introduced into the process chamber and reacts with the first reactant to form a deposited material. A purge step may be carried out between the delivery of each reactant gas to ensure that the only reactions that occur are on the substrate surface. The purge step may be a continuous purge with a carrier gas or a pulse purge between the delivery of the reactant gases.

During the ALD process, the substrate is exposed to various reactive gases including expensive precursors. As the ALD reaction is self-limiting, once the surface reaction has been accomplished, any extra reactive gas is unnecessary and therefore wasted. Since many of the precursors used in ALD are very expensive, this can result in unnecessary expense. There is an ongoing need in the art for improved apparatuses and methods for rapidly processing multiple substrates by atomic layer deposition while minimizing the expense associated with the reactive gases.

### SUMMARY

Embodiments of the invention are directed to deposition systems comprising a processing chamber and a gas distribution apparatus in the processing chamber. The gas distribution apparatus comprises a plurality of elongate gas ports including at least one first reactive gas port in fluid communication with a first reactive gas, at least one second reactive gas port in fluid communication with a second reactive gas different from the first reactive gas, and pump ports surrounding each of the first reactive gas port and second reactive gas port. The pump ports include a first group of pump ports in fluid communication with a first conduit and a second group of pump ports in fluid communication with a second conduit that prevents mixing of the gases flowing through the first group of pump ports and second group of pump ports. Wherein one or more of the first conduit and second conduit is in fluid communication with one or more of a condenser to condense the gas flowing through the conduit and a storage container to store the gas flowing through the conduit.

Some embodiments further comprise at least one purge gas port in fluid communication with a purge gas. The purge gas port are positioned so that each first reactive gas port and second reactive gas port are separated by a purge gas port and the purge gas port surrounded by pump ports.

In one or more embodiments, each of the pump ports surrounding the at least one purge gas port is independently in fluid communication with one of the first conduit and the second conduit.

In some embodiments, one of the pump ports surrounding the at least one purge gas port is in fluid communication with the first conduit and the other of the pump ports surrounding the at least one purge gas port is in fluid communication with the second conduit.

In one or more embodiments, one of the pump ports surrounding the at least one purge gas port is the pump port adjacent the first reactive gas port and the other of the pump ports surrounding the at least one purge gas port is the pump port adjacent the second reactive gas port, so that one of the pump ports is in fluid communication with the first conduit and the other of the pump ports is in fluid communication with the second conduit.

In some embodiments, one of the pump ports surrounding the at least one purge gas port is the pump port adjacent either the first reactive gas port or the second reactive gas port and is in fluid communication with one of the first conduit and second conduit and the other of the pump ports surrounding the at least one purge gas port is in fluid communication with the same conduit and is separated from the other of the first reactive gas port and the second reactive gas port by at least one additional pump port.

In one or more embodiments, the at least one additional pump port is in fluid communication with the other of the first conduit and the second conduit from the adjacent pump port.

In some embodiments, the gas distribution apparatus comprises at least one repeating unit of gas ports, the unit of gas port consisting essentially of, in order, a first reactive gas port, a purge gas port and a second reactive gas port wherein each of the first reactive gas port, purge gas port and second reactive gas port is separated by a pump port.

One or more embodiments further comprise a third reactive gas port in fluid communication with a third reactive gas different from the first reactive gas and the second reactive gas. In an embodiment, the third reactive gas port is surrounded by pump ports.

Some embodiments, further comprise a substrate carrier. The substrate carrier and gas distribution apparatus move with respect to each other in a direction substantially perpendicular to an axis of the elongate gas ports.

In one or more embodiments, one of the first reactive gas ports and the second reactive gas ports are surrounded by two pairs of pump ports, the two pairs of pump ports comprising an inner pair closer to the reactive gas port and an outer pair further from the reactive gas port than the inner pair.

In some embodiments, the inner pair of pump ports is in fluid communication with one of the first conduit and second conduit and the outer pair of pump ports is in communication with the other of the first conduit and second conduit.

In one or more embodiments, when a condenser is in fluid communication with one of the first conduit and second conduit, the condenser condenses the reactive gas and is in fluid communication with a reactive gas source which is in fluid communication with the reactive gas ports to recirculate the collected reactive gas.

Additional embodiments of the invention are directed to deposition systems comprising a processing chamber and a gas distribution apparatus therein. The gas distribution apparatus comprises a plurality of elongate gas ports including, in order, a first reactive gas port in fluid communication with a first reactive gas, a purge gas port in fluid communication with a purge gas, a second reactive gas port in fluid communication with a second reactive gas different from the first reactive gas, and pump ports surrounding each of the first reactive gas port, the purge gas port and the second reactive gas port. The pump ports include a first group of pump ports in fluid communication with a first conduit and a second group of pump ports in fluid communication with a second conduit that prevents mixing of the gases flowing through the first group of pump ports and second group of pump ports. Wherein the pump ports adjacent one of the first reactive gas port and the second reactive gas port are in fluid communication with the first conduit and the pump ports adjacent the other of the first reactive gas port and the second reactive gas port are in fluid communication with the second conduit. One of the first conduit and second conduit is in fluid communication with one or more of a condenser to condense the gas flowing through the conduit and a storage container to store the gas flowing through the conduit.

In some embodiments, at least one of the first reactive gas ports and the second reactive gas ports are surrounded two pairs of pump ports, the two pairs of pump ports comprising an inner pair closer to the reactive gas port and an outer pair further from the reactive gas port than the inner pair.

In one or more embodiments, the inner pair of pump ports is in fluid communication with one of the first conduit and second conduit and the outer pair of pump ports is in communication with the other of the first conduit and second conduit.

Further embodiments of the invention are directed to processing methods comprising simultaneously flowing alternating streams of a first reactive gas from a first reactive gas port and a stream of a second reactive gas from a second reactive gas port over a surface. The first reactive gas is collected from the surface in a first group of pump ports surrounding the first reactive gas port. The second reactive gas is collected from the surface in a second group of pump ports surrounding the second reactive gas port. The gas in the first group of pump ports is directed through a first conduit. The gas in the second group of pump ports is directed through a second conduit separate from the first conduit. At least one of the first conduit and the second conduit is in fluid communication with a condenser or a storage container.

In some embodiments, when the at least one of the first conduit and second conduit is in fluid communication with a condenser, the method further comprises condensing the reactive gas to collect a liquid or solid reactive species from the reactive gas.

One or more embodiments further comprise directing the collected liquid or solid reactive species into a reactive gas source for reuse in the processing method.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional side view of an atomic layer deposition chamber according to one or more embodiments of the invention;

FIG. 2 shows a perspective view of a susceptor in accordance with one or more embodiments of the invention;

FIG. 3 shows a schematic cross-sectional view of an atomic layer deposition chamber in accordance with one or more embodiments of the invention;

FIG. 4 shows a schematic cross-sectional view of gas distribution apparatus in accordance with one or more embodiments of the invention;

FIG. 5 shows a schematic cross-sectional view of an atomic layer deposition chamber in accordance with one or more embodiments of the invention;

FIG. 6 shows a schematic cross-sectional view of gas distribution apparatus in accordance with one or more embodiments of the invention; and

FIG. 7 shows a schematic cross-sectional view of an atomic layer deposition chamber in accordance with one or more embodiments of the invention.

### DETAILED DESCRIPTION

Embodiments of the invention are directed to atomic layer deposition apparatus and methods for the recirculation and reuse of reactive gases. In conventional atomic layer deposition processes, and specifically spatial ALD processes in which the reactive gases are separated in space, as opposed to time, there can be a large loss of excess precursors. In the cases where the cost of materials is high, the spatial ALD hardware, as described herein, allows for the reuse (recirculation) of the precursors.

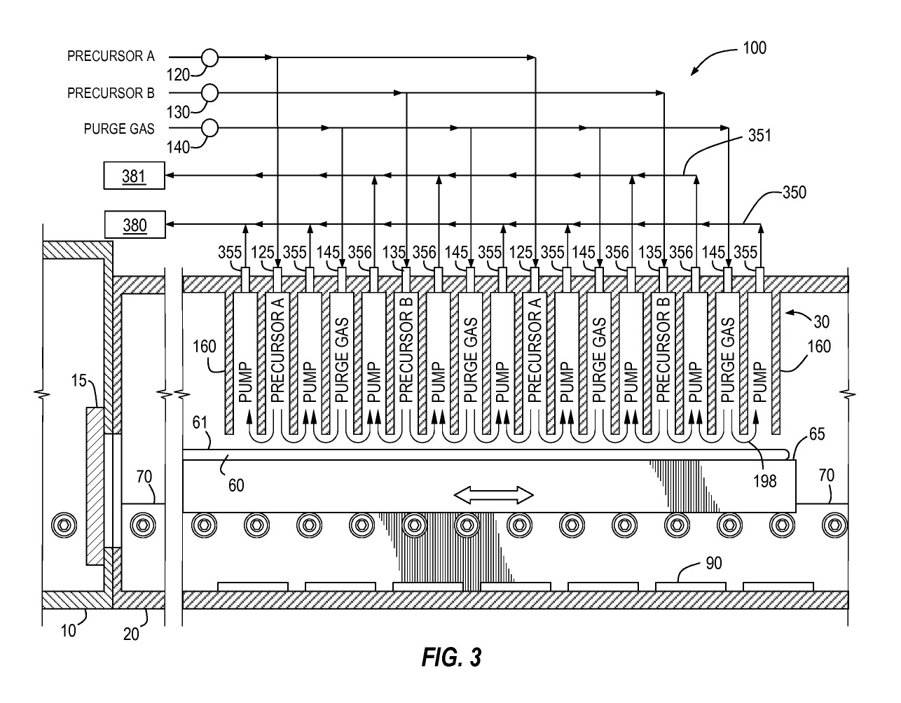

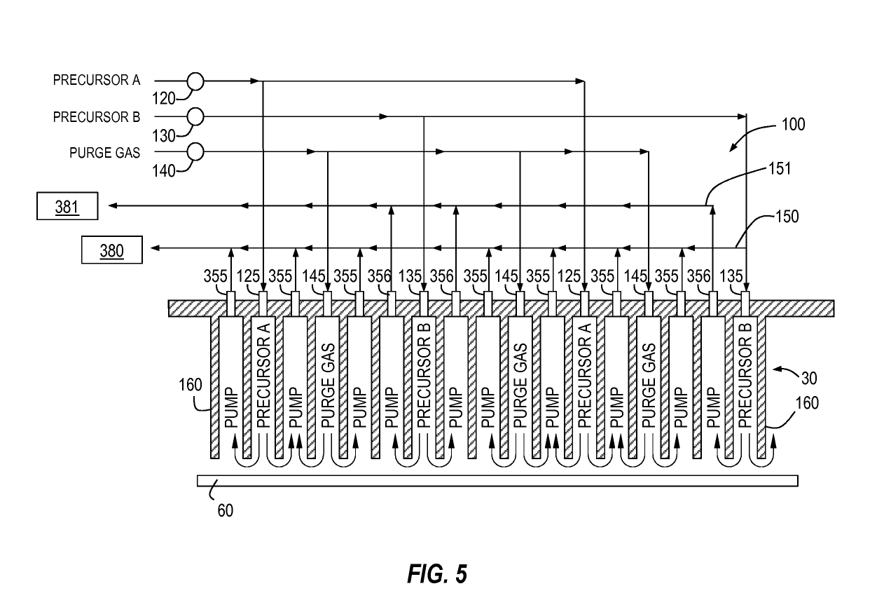

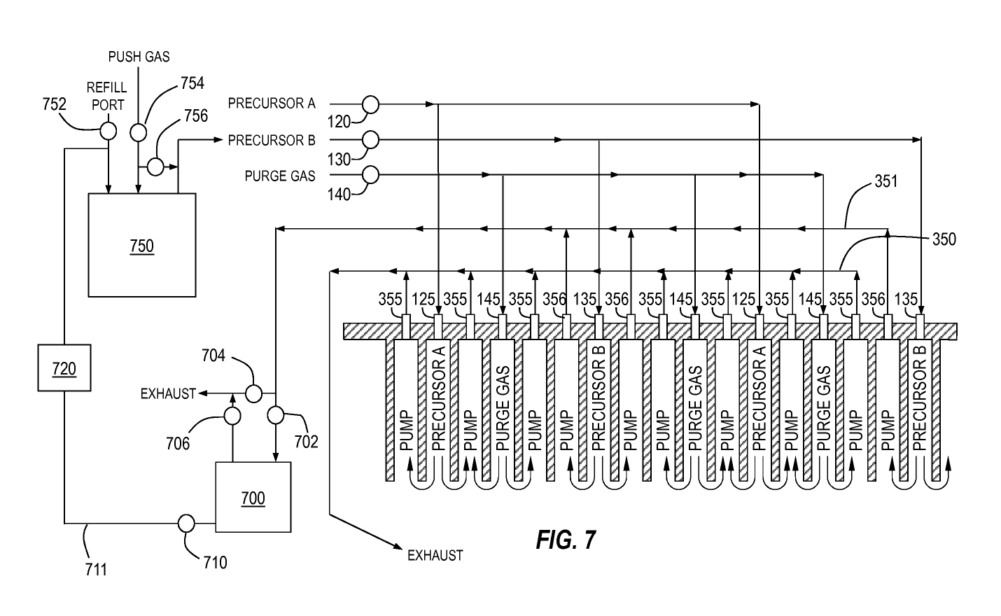

FIG. 3 shows a basic concept of using a condenser for precursor recovery in a Spatial ALD chamber. After a wafer receives precursor B (also referred to as the second reactive gas), which is desirable to be reused, the flow is directed to pump channels and flows to a condenser, where the precursor condenses to liquid or solid state. In FIG. 5, a separate pumping plenum is made around an injection plenum for precursor B. This may reduce the dilution of this precursor by a purge gas flow which is pumped through the separate pumping plenums. FIG. 7 shows a scheme for a liquid precursor, where the ampoule can be refilled periodically through the liquid delivery line connected to a condenser. The filtering devices could be instilled in this line if necessary.

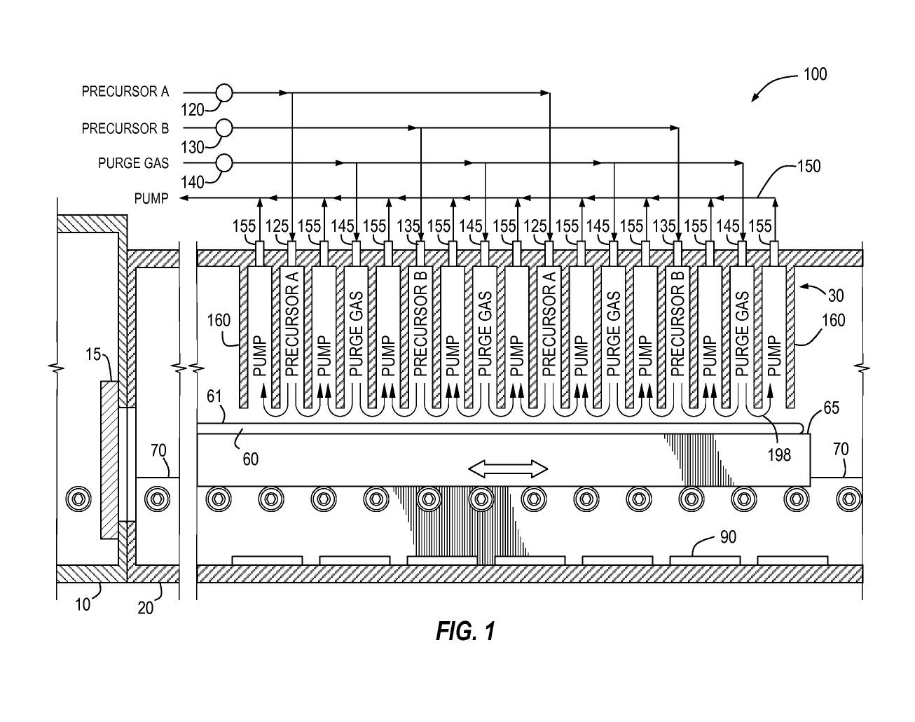

FIG. 1 is a schematic cross-sectional view of an atomic layer deposition system 100 or reactor in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

The gas distribution plate 30 comprises a plurality of gas ports configured to transmit one or more gas streams to the substrate 60 and a plurality of vacuum ports disposed between each gas port and configured to transmit the gas streams out of the processing chamber 20. In the detailed embodiment of FIG. 1, the gas distribution plate 30 comprises a first precursor injector 120, a second precursor injector 130 and a purge gas injector 140. As used in this specification and the appended claims, the term “precursor” means any gas or species used in the atomic layer deposition reaction on the surface of the substrate. The term “precursor” may also be used interchangeably with “reactive gas”. Those skilled in the art will understand that purge gases, inert gases, and species which do not participate in the chemical reaction, are not considered “precursors” or “reactive gases”.

The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The term “vacuum port” is used interchangeably with “pump port”. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60. For example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads may be employed.

In operation, a substrate 60 is delivered (e.g., by a robot) to the load lock chamber 10 and is placed on a shuttle 65. After the isolation valve 15 is opened, the shuttle 65 is moved along the track 70. Once the shuttle 65 enters in the processing chamber 20, the isolation valve 15 closes, sealing the processing chamber 20. The shuttle 65 is then moved through the processing chamber 20 for processing. In one embodiment, the shuttle 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 61 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 61 and around the lower portions of the partitions 160, and finally upward toward the vacuum ports 155. In this manner, each gas may be uniformly distributed across the substrate surface 61. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discreet steps.

Sufficient space is generally provided at the end of the processing chamber 20 so as to ensure complete exposure by the last gas port in the processing chamber 20. Once the substrate 60 reaches the end of the processing chamber 20 (i.e., the first surface 61 has completely been exposed to every gas port in the chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 61 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 61. The width between each partition, the number of gas ports disposed on the processing chamber 20, and the number of times the substrate is passed back and forth may also determine the extent to which the substrate surface 61 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 61 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In yet another embodiment, the system 100 may be configured to process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber. In one or more embodiments, at least one radiant heat lamp 90 is positioned to heat the second side of the substrate 60.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

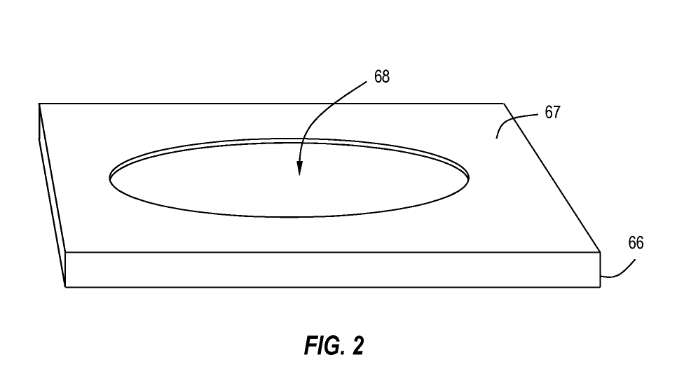

In still another embodiment, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In detailed embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

FIG. 3 shows a view of a gas distribution plate 30 in which the vacuum ports 155, 156 are directed to different destinations. In the embodiment shown in FIG. 3, the vacuum ports 155 evacuate gases from the gas injector 125 and purge injector 145 to a first destination pump or exhaust line. Second vacuum ports 156 evacuate gases from the gas injector 135 and the purge gas injectors 145 to a different destination from the vacuum ports 155. In one or more embodiments, the destinations are selected from exhaust and condensers.

In some embodiments, the exhaust lines are split with each having a separate destination. For example, FIG. 3 shows an embodiment of the invention in which a gas distribution apparatus evacuates gases to two separate locations or destinations. As used in this specification and the appended claims, the term “destination” means any intermediate or final condition or location. For example, a destination could be an exhaust line, a cold drop, a condenser, a storage facility or container, as well as other possible destinations.

In the embodiment shown in FIG. 3, the gas distribution apparatus 100 includes a plurality of elongate gas ports as previously described with respect to FIG. 1. The elongate gas ports include at least one first reactive gas port 125 in fluid communication with a first reactive gas 120 and at least one second reactive gas port 135 in fluid communication with a second reactive gas 130 which is different from the first reactive gas 120. As used in this specification and the appended claims the terms “fluid communication”, “communication” and the like mean that there is a path allowing the gas to flow. The first reactive gas 120 may be referred to as reactive gas A or precursor A, and the like, and the second reactive gas 130 may be referred to as a second reactive gas B or precursor B, and the like. It will be understood by those skilled in the art that the reactive gases are gases which have a reaction with the surface of the substrate or a species on the surface of the substrate.

The gas distribution plate 30 in FIG. 3 also includes pump ports 355, 356, also referred to as vacuum ports, surrounding each of the first reactive gas ports 125 and second reactive gas ports 135. The pump ports 355, 356 are separated into a first group of pump ports 355 in fluid communication with a first conduit 350 and a second group of pump ports 356 in fluid communication with a second conduit 351 that prevents mixing of the gases flowing through the first group of pump ports 355 and second group of pump ports 356.

The gases flowing through the first group of pump ports 355 into the first conduit 350 are conducted to a first destination 380. The gases flowing through the second group of pump ports 356 into the second conduit 351 are conducted to a second destination 381. The destinations can be independently, for example, an exhaust line, a cold drop, a condenser or a storage container. In some embodiments, one or more of the first conduit 350 and second conduit 351 is in fluid communication with one or more of a condenser to condense the gas flowing through the conduit and a storage container to store the gas flowing through the conduit. The storage container can be any suitable storage container including, but not limited to, a gas cylinder. The storage container can be used to temporarily store the gas so that it can be recycled or purified at a later time.

Some embodiments further comprise at least one purge gas port 145 in fluid communication with a purge gas 140. The purge gas port is positioned so that each first reactive gas port 125 and second reactive gas port 135 are separated by a purge gas port 145 so that the purge gas ports 145 are surrounded by pump ports 355, 356.

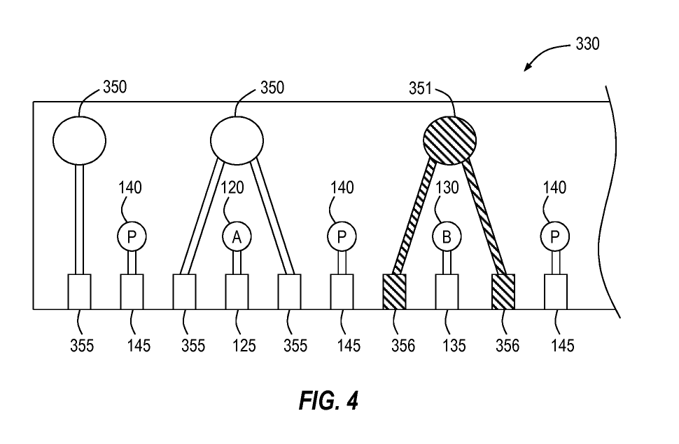

In one or more embodiments, each of the pump ports 355, 356 surrounding the at least one purge gas port 145 is independently in fluid communication with one of the first conduit 350 and the second conduit 351. FIG. 4 shows a cross sectional view of a portion of a gas distribution plate similar to the plate shown in FIG. 3. Here it can be seen that the sequence of gas ports, from left-to-right, includes a pump port 355 in communication with a first conduit 350, a purge port 145, a pump port 355 in fluid communication with the first conduit 350, a first reactive gas port 125, a pump port 355 in communication with the first conduit 350, a purge port 145, a pump port 356 in communication with the second conduit 351, a second reactive gas port 135, a pump port 356 in communication with the second conduit 351 and a purge port. The gas distribution plate 330 can continue with additional ports extending the sequence. It can be seen that one of the pump ports 355, 356 surrounding the at least one purge gas port 145 (the middle purge gas port 145) is in fluid communication with the first conduit 350 and the other of the pump ports 356 surrounding the at least one purge gas injector 145 is in fluid communication with the second conduit 351.

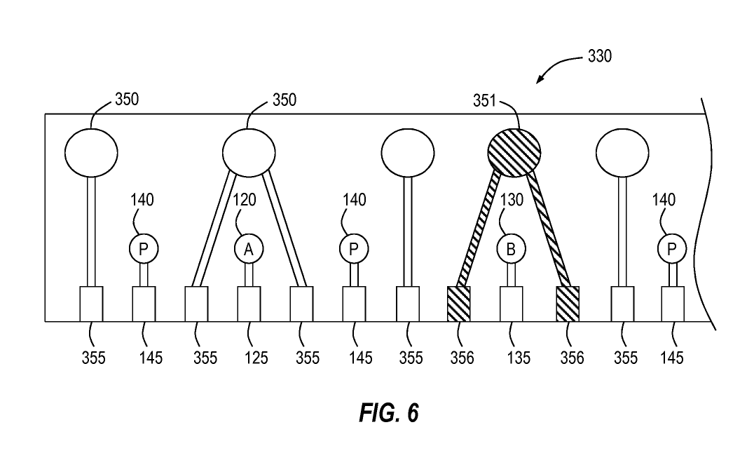

In some embodiments, one of the pump ports 355, 356 surrounding the at least one purge gas port 145 is the pump port 355, 356 adjacent either the first reactive gas port 125 or the second reactive gas port 135 and is in fluid communication with one of the first conduit 350 and second conduit 351 and the other of the pump ports 355, 356 surrounding the at least one purge gas port 145 is in fluid communication with the same conduit 350, 351 and is separated from the other of the first reactive gas port 125 and the second reactive gas port 135 by at least one additional pump port 355, 356. In one or more embodiments, the at least one additional pump port 355, 356 is in fluid communication with the other of the first conduit 350 and the second conduit 351 from the adjacent pump port 355, 356. Referring to FIGS. 5 and 6, it can be seen that the sequence of ports, from left-to-right, includes a pump port 355 in communication with a first conduit 350, a purge port 145, a pump port 355 in communication with a first conduit 350, a first reactive gas port 125, a pump port 355 in communication with the first conduit 350, a purge port 145, a pump port 355 in communication with the first conduit 350, a pump port 356 in communication with the second conduit 351, a second reactive gas port 135, a pump port 356 in communication with the second conduit 351, a pump port 355 in communication with the first conduit 350 and a purge port 145. The pattern can continue for as many iterations as desired, as in FIG. 5 which shows two repeating units of gas ports. Without being bound by any particular theory of operation, it is believed that including the additional pump ports will provide a gas in the conduit which has less dilution from the purge gas than would otherwise be possible. Essentially, the purge gas will flow up one pump port 355 and the reactive gas will flow up the adjacent pump port 356 so that there is minimal dilution of the reactive gas with the purge gas. It will be understood by those skilled in the art that there will be some flow of purge gas into the pump port 356 and some flow of reactive gas into pump port 355.

Stated differently, in some embodiments, one of the first reactive gas ports 125 and the second reactive gas ports 135 are surrounded by two pairs of pump ports 355, 356. The two pairs of pump ports 355, 356 comprise an inner pair closer to the reactive gas port and an outer pair further from the reactive gas port than the inner pair. Referring again to FIG. 6, the inner pair of pump ports 356 is in fluid communication with one of the first conduit 350 and second conduit 351 (shown) and the outer pair of pump ports 355 is in communication with the other of the first conduit (shown) and second conduit. Those skilled in the art will understand that these conduit connections can be reversed and mixed as desired.

In some embodiments, the gas distribution apparatus comprises at least one repeating unit of gas injectors. A unit of gas injectors consists essentially of, in order, a first reactive gas injector, a purge gas injector and a second reactive gas injector wherein each of the first reactive gas injector, purge gas injector and second reactive gas injector is separated by a pump port. As used in this context, and in the appended claims, the term “consisting essentially of” means that the gas distribution plate does not include any additional gas ports for reactive gases. Ports for non-reactive gases (e.g., purge gases) and vacuum can be interspersed throughout while still being within the consisting essentially of clause. For example, the gas distribution plate may have eight vacuum ports V and four purge ports P but still consist essentially of a first reactive gas port, a purge gas port and a second reactive gas port.

In one or more embodiments, the gas distribution plate consists essentially of, in order, a leading first reactive gas port, a second reactive gas port and a trailing first reactive gas port A′ wherein each of the first reactive gas ports and second reactive gas ports are separated by a pump port. Embodiments of this variety may be referred to as an ABA configuration. Without being bound by any particular theory of operation, it is believed that configurations of this sort may allow for the rapid reciprocal deposition of a film.

Some embodiments further comprise a third reactive gas injector in fluid communication with a third reactive gas different from the first reactive gas and the second reactive gas. The third reactive gas injector may be is surrounded by pump ports as well, which can independently be in communication with the first conduit 350, the second conduit 351 or even a third conduit (not shown).

FIG. 7 shows an embodiment of the invention in which the first conduit 350 directs the flow of gas to an exhaust system and the second conduit 351 directs the gas flow to a condenser 700. When a condenser 700 is in fluid communication with one of the first conduit 350 and second conduit 351, the condenser 700 condenses the reactive gas to provide a reactive species suitable for reuse in the ALD process. The reactive species can be a solid, liquid or gas. In some embodiments, the condenser 700 is in fluid communication with a reactive gas source 750 which is in fluid communication with the reactive gas injector 130 to recirculate the collected reactive gas. The reactive gas source 750 can be any suitable reactive gas source known to those skilled in the art and can include, but is not limited to, a precursor ampoule.

In the embodiment of FIG. 7, the second conduit 351 connects to the condenser 700 through an inlet valve 702. Opening and closing the inlet valve 702 can allow the flow of gas into the condenser to be started and stopped as desired. Additionally, the gas can be allowed to flow through a bypass valve 704 to be exhausted from the system. The bypass valve 704 and inlet valve 702 can be opened and closed in simultaneous or alternating patterns depending on the desired flow profile of gases into the condenser 700 and to the exhaust. An outlet valve 706 connects the condenser to the exhaust allowing the gases which have not condensed to be evacuated from the system.

In some embodiments, the condenser 700 includes a transfer line 711 and transfer valve 710 which allows the condensed material to be removed from the condenser 700 without needing to remove the inlet and outlet connections. The transfer line 711 can be connected to any number of separate devices including storage containers, ampoules and the like. A filtration device 720 can be included on the transfer line 711 if necessary. The filtration device 720 can be any suitable filtration system and may, for example, be used to remove particulates from the condensed material.

In one or more embodiments, the transfer valve 710 and transfer line allow the condensed, recovered reactive species to be transferred to the same reactive gas source 750 (e.g., ampoule) that is used to supply the reactive gas to the gas distribution plate. As shown in FIG. 7, the reactive species can be moved from the condenser to the reactive gas source 750 by connection to the refill port of the reactive gas source 750. The refill port may include a refill valve 752 which allows access to the interior of the reactive gas source 750 so that the device can be refilled with unused or recirculated reactive gas or reactive species. Those skilled in the art will understand that the term “reactive gas source” is used to mean a source for providing a reactive species to the processing chamber, and does not require that the species within the reactive gas source is a gas. In some embodiments, the reactive gas source holds one or more of a solid, liquid or gas which can be sublimated, boiled and/or transferred to the processing chamber. A push gas is connected to the reactive gas source 750 through a push valve 754. The push gas is used to move the reactive species from the inside of the reactive gas source 750 to the processing chamber. The push valve 754 can be closed to prevent gas from backfilling into the condenser 750 when the transfer valve 710 is open. A bypass valve 756 may also be included which connects the push gas directly to the processing chamber so that the push gas does not need to pass through the reactive gas source 750. Those skilled in the art will understand that there are other valves present on the reactive gas source 750 which allow the source to be isolated from the processing chamber and the environment, allowing the source to be removed without allowing ambient air into the processing chamber.

Some embodiments of the invention are directed to a deposition system including a processing chamber with a gas distribution apparatus therein. The term gas distribution apparatus can be used to describe a gas distribution plate or a showerhead type device and may include the connections to and from the processing chamber. The gas distribution apparatus of some embodiments comprises a plurality of elongate gas ports including, in order, a first reactive gas port 125 in fluid communication with a first reactive gas injector 120, a purge gas port 145 in fluid communication with a purge gas injector 140 and a second reactive gas port 135 in fluid communication with a second reactive gas which is different from the first reactive gas. Pump ports 355, 356 surround each of the first reactive gas port 125, the purge gas port 145 and the second reactive gas port 135. The pump ports 355, 356 include a first group of pump ports 355 in fluid communication with a first conduit 350 and a second group of pump ports 356 in fluid communication with a second conduit 351 that prevents mixing the gases flowing through the first group of pump ports 355 with the gases flowing through the second group of pump ports 356 and the gases in the first conduit 350 from mixing with the gases in the second conduit 351. The pump ports 355, 356 adjacent one of the first reactive gas port 125 and the second reactive gas port 135 are in fluid communication with the first conduit 350 and the pump ports 355, 356 adjacent the other of the first reactive gas port 125 and the second reactive gas port 135 are in fluid communication with the second conduit 351. One of the first conduit 350 and second conduit 351 is in fluid communication with one or more of a condenser 700 to condense the gas flowing through the conduit and a storage container (not shown) to store the gas flowing through the conduit. Those skilled in the art will understand that a storage container can include one or more inlets, like on a typical gas cylinder. The storage container may include a second valve which allows for pressure equalization and the flow of gases into the storage container, but this may not be necessary.

In one or more embodiments, at least one of the first reactive gas ports 125 and the second reactive gas ports 135 are surrounded two pairs of pump ports 355, 356. The two pairs of pump ports 355, 356 comprise an inner pair closer to the reactive gas port and an outer pair further from the reactive gas port than the inner pair. This is shown in the embodiment of FIGS. 5-7. In some embodiments, the inner pair of pump ports is in fluid communication with one of the first conduit 350 and second conduit 351 and the outer pair of pump ports is in communication with the other of the first conduit 350 and second conduit 351.

Additional embodiments of the invention are directed to processing methods. Simultaneous alternating streams of a first reactive gas and a second reactive gas are flowed from a first reactive gas port and a second reactive gas port, respectively, over the surface of a substrate. The gas streams are flowing simultaneously and spacially separated to alternate. The first reactive gas from the surface is collected in a first group of pump ports surrounding the first reactive gas port. The second reactive gas is collected from the surface in a second group of pump ports surrounding the second reactive gas port. The gas in the first group of pump ports is directed through a first conduit and the gas from the second group of pump ports is directed through a second conduit separate from the first conduit. At least one of the first conduit and the second conduit is in fluid communication with a condenser or storage container.

In some embodiments, the at least one of the first conduit 350 and second conduit 351 is in fluid communication with a condenser 700 and the method further comprises condensing the reactive gas to collect a liquid or solid reactive species from the reactive gas. One or more embodiments further comprise directing the collected liquid or solid reactive species into a reactive gas source 750 for reuse in the processing method.

The gas distribution plates or apparatus can have any suitable number of gas ports to deposit layers on the substrate. In detailed embodiments, the gas distribution apparatus comprises a sufficient number of gas ports to process in the range of about 10 to about 100 atomic layer deposition cycles or up to about 20, 25, 27, 30, 32, 35, 37, 40, 42, 45, 47, 50 or 100 atomic layer deposition cycles.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not be required. Indeed, other embodiments relate to deposition processes under very mild conditions without a plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A deposition system, comprising:
a processing chamber; and
a gas distribution apparatus in the processing chamber, the gas distribution apparatus comprising a plurality of elongate gas ports including at least one first reactive gas port in fluid communication with a first reactive gas, at least one second reactive gas port in fluid communication with a second reactive gas different from the first reactive gas, and pump ports surrounding each of the first reactive gas port and second reactive gas port, the pump ports including a first group of pump ports in fluid communication with a first conduit and a second group of pump ports in fluid communication with a second conduit that prevents mixing of the gases flowing through the first group of pump ports and second group of pump ports, wherein one or more of the first conduit and second conduit is in fluid communication with one or more of a condenser to condense the gas flowing through the conduit and a storage container to store the gas flowing through the conduit.

2. The deposition system of claim 1, further comprising at least one purge gas port in fluid communication with a purge gas, the purge gas port positioned so that each first reactive gas port and second reactive gas port are separated by a purge gas port, the purge gas port surrounded by pump ports.

3. The deposition system of claim 2, wherein each of the pump ports surrounding the at least one purge gas port is independently in fluid communication with one of the first conduit and the second conduit.

4. The deposition system of claim 3, wherein one of the pump ports surrounding the at least one purge gas port is in fluid communication with the first conduit and the other of the pump ports surrounding the at least one purge gas port is in fluid communication with the second conduit.

5. The deposition system of claim 3, wherein one of the pump ports surrounding the at least one purge gas port is the pump port adjacent the first reactive gas port and the other of the pump ports surrounding the at least one purge gas port is the pump port adjacent the second reactive gas port, so that one of the pump ports is in fluid communication with the first conduit and the other of the pump ports is in fluid communication with the second conduit.

6. The deposition system of claim 3, wherein one of the pump ports surrounding the at least one purge gas port is the pump port adjacent either the first reactive gas port or the second reactive gas port and is in fluid communication with one of the first conduit and second conduit and the other of the pump ports surrounding the at least one purge gas port is in fluid communication with the same conduit and is separated from the other of the first reactive gas port and the second reactive gas port by at least one additional pump port.

7. The deposition system of claim 6, wherein the at least one additional pump port is in fluid communication with the other of the first conduit and the second conduit from the adjacent pump port.

8. The deposition system of claim 2, wherein the gas distribution apparatus comprises at least one repeating unit of gas ports, the unit of gas port consisting essentially of, in order, a first reactive gas port, a purge gas port and a second reactive gas port wherein each of the first reactive gas port, purge gas port and second reactive gas port is separated by a pump port.

9. The deposition system of claim 2, further comprising a third reactive gas port in fluid communication with a third reactive gas different from the first reactive gas and the second reactive gas.

10. The deposition system of claim 9, wherein the third reactive gas port is surrounded by pump ports.

11. The deposition system of claim 1, further comprising a substrate carrier, wherein the substrate carrier and gas distribution apparatus move with respect to each other in a direction substantially perpendicular to an axis of the elongate gas ports.

12. The deposition system of claim 1, wherein one of the first reactive gas ports and the second reactive gas ports are surrounded by two pairs of pump ports, the two pairs of pump ports comprising an inner pair closer to the reactive gas port and an outer pair further from the reactive gas port than the inner pair.

13. The deposition system of claim 12, wherein the inner pair of pump ports is in fluid communication with one of the first conduit and second conduit and the outer pair of pump ports is in communication with the other of the first conduit and second conduit.

14. The deposition system of claim 1, wherein when a condenser is in fluid communication with one of the first conduit and second conduit, the condenser condenses the reactive gas and is in fluid communication with a reactive gas source which is in fluid communication with the reactive gas ports to recirculate the collected reactive gas.

15. A deposition system, comprising:
a processing chamber; and
a gas distribution apparatus in the processing chamber, the gas distribution apparatus comprising a plurality of elongate gas ports including, in order, a first reactive gas port in fluid communication with a first reactive gas, a purge gas port in fluid communication with a purge gas, a second reactive gas port in fluid communication with a second reactive gas different from the first reactive gas, and pump ports surrounding each of the first reactive gas port, the purge gas port and the second reactive gas port, the pump ports including a first group of pump ports in fluid communication with a first conduit and a second group of pump ports in fluid communication with a second conduit that prevents mixing of the gases flowing through the first group of pump ports and second group of pump ports, wherein the pump ports adjacent one of the first reactive gas port and the second reactive gas port are in fluid communication with the first conduit and the pump ports adjacent the other of the first reactive gas port and the second reactive gas port are in fluid communication with the second conduit, wherein one of the first conduit and second conduit is in fluid communication with one or more of a condenser to condense the gas flowing through the conduit and a storage container to store the gas flowing through the conduit.

16. The deposition system of claim 15, wherein at least one of the first reactive gas ports and the second reactive gas ports are surrounded two pairs of pump ports, the two pairs of pump ports comprising an inner pair closer to the reactive gas port and an outer pair further from the reactive gas port than the inner pair.

17. The deposition system of claim 16, wherein the inner pair of pump ports is in fluid communication with one of the first conduit and second conduit and the outer pair of pump ports is in communication with the other of the first conduit and second conduit.

18. A processing method comprising:
flowing simultaneous alternating streams of a first reactive gas from a first reactive gas port and a stream of a second reactive gas from a second reactive gas port over a surface; and
collecting first reactive gas from the surface in a first group of pump ports surrounding the first reactive gas port;
collecting second reactive gas from the surface in a second group of pump ports surrounding the second reactive gas port;
directing the gas in the first group of pump ports through a first conduit; and
directing the gas in the second group of pump ports through a second conduit separate from the first conduit, wherein at least one of the first conduit and the second conduit is in fluid communication with a condenser or a storage container.

19. The method of claim 18, wherein when the at least one of the first conduit and second conduit is in fluid communication with a condenser, the method further comprises condensing the reactive gas to collect a liquid or solid reactive species from the reactive gas.

20. The method of claim 19, further comprising directing the collected liquid or solid reactive species into a reactive gas source for reuse in the processing method.
